(19) United States
(12) Patent Application Publication
(10) Pub. No.: US 2026/0334176 A1
(43) Pub. Date: Oct. 22, 2026

(54) SUBSTRATE PROCESSING METHOD, METHOD OF MANUFACTURING SEMICONDUCTOR DEVICE, SUBSTRATE PROCESSING APPARATUS AND NON-TRANSITORY COMPUTER-READABLE RECORDING MEDIUM

(71) Applicant: Kokusai Electric Corporation, Tokyo (JP)

(72) Inventors: Koichi KARASAWA, Toyama-shi (JP); Sadayoshi HORII, Toyama-shi (JP); Tatsushi UEDA, Toyama-shi (JP); Toru KAKUDA, Toyama-shi (JP)

(73) Assignee: Kokusai Electric Corporation, Tokyo (JP)

(21) Appl. No.: 19/566,022

(22) Filed: Mar. 13, 2026

(30) Foreign Application Priority Data
Apr. 10, 2025 (JP) 2025-065154
Feb. 24, 2026 (JP) 2026-027169

(51) Int. Cl. H10P 95/90; C25D 3/12; C25D 3/50; C25D 5/00; C25D 5/54; C25D 7/12; H10W 20/00

(52) U.S. Cl. CPC H10P 95/90; C25D 3/12; C25D 3/50; C25D 5/003; C25D 5/54; C25D 7/12; H10W 20/056

(57) ABSTRACT

It is possible to control a quality of a metal-containing film formed on a substrate. There is provided a technique that includes: (a) removing impurities from a metal-containing film by supplying a carboxyl group-containing fluid to a substrate provided with the metal-containing film at a first pressure and a first temperature; (b) setting a pressure applied to the substrate to a second pressure lower than the first pressure by exhausting an atmosphere around the substrate while stopping a supply of the carboxyl group-containing fluid; and (c) increasing a crystal grain size of a metal component in the metal-containing film by heating the substrate to a second temperature higher than the first temperature while setting the pressure applied to the substrate to the second pressure and while exposing the metal-containing film from which the impurities are removed.

### DESCRIPTION

### CROSS-REFERENCE TO RELATED PATENT APPLICATION

This non-provisional U.S. patent application is based on and claims priority under 35 U.S.C. § 119 of Japanese Patent Application No. 2025-065154, filed on Apr. 10, 2025, and Japanese Patent Application No. 2026-027169, filed on Feb. 24, 2026, in the Japanese Patent Office, the entire contents of which are hereby incorporated by reference.

### BACKGROUND

### 1. Field

The present disclosure relates to a substrate processing method, a method of manufacturing a semiconductor device, a substrate processing apparatus and a non-transitory computer-readable recording medium.

### 2. Related Art

According to some related arts, as a part of a manufacturing process of a semiconductor device, a modification process of modifying a film formed on a substrate may be performed.

### SUMMARY

According to the present disclosure, there is provided a technique capable of controlling a quality of a metal-containing film formed on a substrate.

According to an embodiment of the present disclosure, there is provided a technique that includes: (a) removing impurities from a metal-containing film by supplying a carboxyl group-containing fluid to a substrate provided with the metal-containing film at a first pressure and a first temperature; (b) setting a pressure applied to the substrate to a second pressure lower than the first pressure by exhausting an atmosphere around the substrate while stopping a supply of the carboxyl group-containing fluid; and (c) increasing a crystal grain size of a metal component in the metal-containing film by heating the substrate to a second temperature higher than the first temperature while setting the pressure applied to the substrate to the second pressure and while exposing the metal-containing film from which the impurities are removed.

### BRIEF DESCRIPTION OF THE DRAWINGS

FIG. 1 is a diagram schematically illustrating a vertical cross-section of a process furnace (vertical type process furnace) 202 of a substrate processing apparatus preferably used in one or more embodiments of the present disclosure.

FIG. 2 is a block diagram schematically illustrating a configuration of a controller 121 and its related components of the substrate processing apparatus preferably used in the embodiments of the present disclosure.

FIG. 3 is a diagram schematically illustrating a process sequence according to the embodiments of the present disclosure.

FIG. 4A is a diagram schematically illustrating a partially enlarged cross-section of a wafer 200 provided with a metal-containing film 400 in a recess (concave structure), FIG. 4B is a diagram schematically illustrating a partially enlarged cross-section of the wafer 200 after impurities 305 are removed from the metal-containing film 400 by supplying a carboxyl group-containing fluid to the metal-containing film 400 at a first temperature, and FIG. 4C is a diagram schematically illustrating a partially enlarged cross-section of the wafer 200 after a metal-containing film 410 (from which the impurities 305 have been removed) is heated to a second temperature in a state where a process chamber 201 is under reduced pressure.

FIG. 5A is a diagram schematically illustrating a partially enlarged view of crystal grains 300 in the metal-containing film 400 before a step “A” is performed, FIG. 5B is a diagram schematically illustrating a partially enlarged view of crystal grains 310 in the metal-containing film 410 after the step “A” is performed, and FIG. 5C is a diagram schematically illustrating a partially enlarged view of crystal grains 320 in a metal-containing film 420 after steps “B” and “C” are performed.

FIG. 6 is a diagram schematically illustrating a vertical cross-section of a process furnace (vertical type process furnace) 302 of a substrate processing apparatus preferably used in another embodiment of the present disclosure.

### DETAILED DESCRIPTION

### Embodiments of Present Disclosure

Hereinafter, one or more embodiments (hereinafter, also simply referred to as “embodiments”) according to the present disclosure will be described with reference to the drawings. For example, the drawings used in the following description are all schematic, and a relationship between dimensions of each component and a ratio of each component shown in the drawing may not always match the actual ones. In addition, even between the drawings, the relationship between the dimensions of each component and the ratio of each component may not always match.

### 1. Configuration of Processing Apparatus

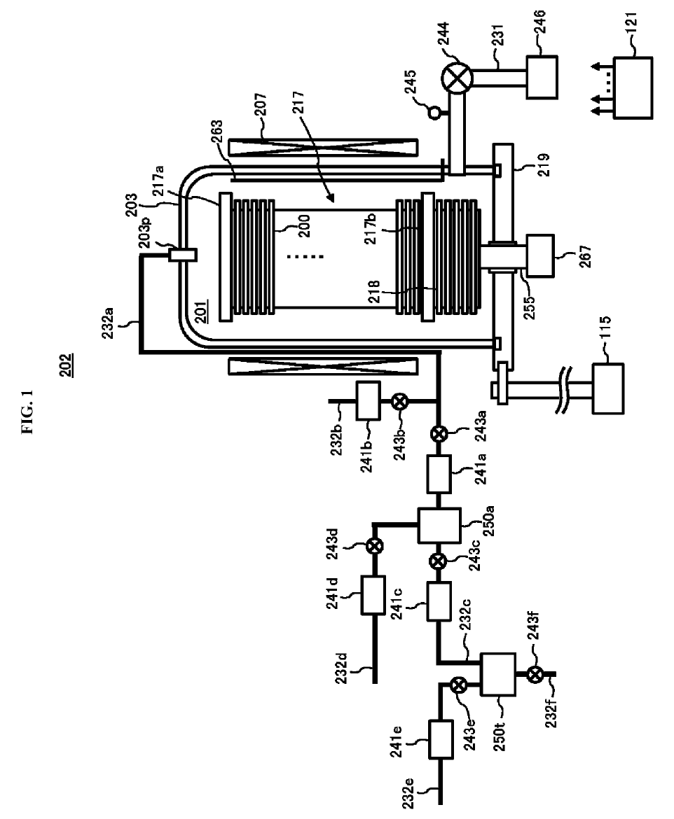

As shown in FIG. 1, a process furnace 202 of a substrate processing apparatus includes a reaction tube 203. For example, the reaction tube 203 is configured as a cylinder provided with a gas supply port 203p at an upper end thereof and a furnace opening (also referred to as an “opening”) at a lower end thereof. A process chamber 201 is provided in a hollow cylindrical portion of the reaction tube 203. The process chamber 201 is configured to accommodate a plurality of wafers 200. Hereinafter, each of the plurality of wafers 200 may also be referred to as a “wafer 200” serving as a substrate.

A seal cap 219 serving as a lid capable of airtightly closing the opening (lower end opening) of the reaction tube 203 is provided under the reaction tube 203. A rotator (which is a rotating structure) 267 is installed below the seal cap 219. A rotating shaft 255 of the rotator 267 is connected to a boat 217. The rotator 267 is configured to rotate the wafers 200 accommodated in the boat 217 by rotating the boat 217. The seal cap 219 is configured to be elevated or lowered in a vertical direction by a boat elevator 115 serving as an elevator (which is an elevating structure).

The boat 217 serving as a substrate retainer is configured to align the plurality of the wafers 200 (for example, from 25 wafers to 200 wafers) in the vertical direction and supports the plurality of the wafers 200 in a multi-stage manner, while the plurality of the wafers 200 are horizontally oriented with their centers aligned with each other. That is, the boat 217 supports the plurality of the wafers 200 with predetermined intervals therebetween. The boat 217 includes a top plate 217a and a bottom plate 217b at a top and a bottom thereof. A plurality of heat insulators 218 are supported in a multi-stage manner in a horizontal orientation under the boat 217.

A heater 207 serving as a heating structure (heating apparatus) is provided outside the reaction tube 203. The heater 207 is configured to heat the wafers 200 accommodated in a wafer accommodation region (wafer accommodation area) to a predetermined temperature. In addition, the heater 207 may function as a liquefaction suppressor (which is a liquefaction suppressing structure) configured to apply thermal energy to a gas supplied into the process chamber 201 to suppress its liquefaction, or may function as an exciter (which is an excitation structure) configured to activate the gas by heat. A temperature sensor 263 serving as a temperature detector is provided in the process chamber 201 (in which the wafers 200 are accommodated) along an inner wall of the reaction tube 203.

A gas supply pipe 232a is connected to the gas supply port 203p provided at the upper end of the reaction tube 203. A gas generator (gas generating structure) 250a serving as a vaporizer, a mass flow controller (MFC) 241a serving as a flow rate controller (flow rate control structure) and a valve 243a serving as an opening/closing valve are sequentially installed in this order at the gas supply pipe 232a from an upstream side to a downstream side of the gas supply pipe 232a.

A supply pipe 232c is connected to the gas generator 250a. A liquid containing a carboxyl group (-COOH) (hereinafter, also referred to as a “first liquid”) is supplied through the supply pipe 232c. A tank 250t (which is configured to store the first liquid), an MFC 241c and a valve 243c are installed at the supply pipe 232c. The first liquid will be described later in detail.

A gas supply pipe 232e is connected to the tank 250t. A pressurized gas is supplied into the tank 250t through the gas supply pipe 232e. An MFC 241e and a valve 243e are installed at the gas supply pipe 232e. The pressurized gas is used to push the first liquid from the tank 250t into the supply pipe 232c. For example, the pressurized gas may be a gas similar to an inert gas described later. A drain pipe 232fis further installed at the tank 250t. The first liquid is discharged from an inside (inner portion) of the tank 250t through the drain pipe 232f. A valve 243f is installed at the drain pipe 232f.

A gas supply pipe 232d is connected to the gas generator 250a. A vaporization carrier gas is supplied into the gas generator 250a through the gas supply pipe 232d. An MFC 241d and a valve 243d are installed at the gas supply pipe 232d. The vaporization carrier gas is used to atomize the first liquid supplied to the gas generator 250a from the supply pipe 232c such that the first liquid is easily vaporized.

A gas supply pipe 232b through which the inert gas is supplied is connected to a downstream side of the valve 243a provided at the gas supply pipe 232a. An MFC 241b and a valve 243b are installed at the gas supply pipe 232b. For example, the inert gas acts as a purge gas, a carrier gas or a dilution gas.

The gas generator 250a is configured to generate a -COOH-containing fluid (which is a vaporized gas of the first liquid) by heating the first liquid to a predetermined temperature, for example, under an approximately atmospheric pressure, and vaporizing or misting the first liquid. According to the present embodiments, when vaporizing or misting the first liquid, the vaporization carrier gas is supplied to the gas generator 250a together with the first liquid. Thereby, it is possible to atomize the first liquid.

A -COOH-containing fluid supplier (which is a -COOH-containing fluid supply system or a -COOH-containing fluid supply structure) is constituted mainly by the gas supply pipe 232a, the MFC 241a and the valve 243a. The -COOH-containing fluid supplier may further include the gas generator 250a. An inert gas supplier (which is an inert gas supply system or an inert gas supply structure) is constituted mainly by the gas supply pipe 232b, the MFC 241b and the valve 243b. A first liquid supplier (which is a first liquid supply system or a first liquid supply structure) is constituted mainly by the tank 250t, the supply pipe 232c, the MFC 241c and the valve 243c. A vaporization carrier gas supplier (which is a vaporization carrier gas supply system or a vaporization carrier gas supply structure) is constituted mainly by the gas supply pipe 232d, the MFC 241d and the valve 243d. A pressurized gas supplier (which is a pressurized gas supply system or a pressurized gas supply structure) is constituted mainly by the gas supply pipe 232e, the MFC 241e and the valve 243e. The -COOH-containing fluid supplier, the first liquid supplier, the vaporization carrier gas supplier and the pressurized gas supplier may also be collectively referred to as a supplier (which is a supply system or a supply structure).

An exhaust pipe 231 through which an atmosphere (inner atmosphere) of the process chamber 201 is exhausted is connected to a lower portion of a side wall of the reaction tube 203. A vacuum pump 246 serving as an exhaust apparatus is connected to the exhaust pipe 231 via a pressure sensor 245 and an APC valve 244. The pressure sensor 245 serves as a pressure detector configured to detect a pressure (inner pressure) of the process chamber 201, and the APC valve 244 serves as a pressure regulator (which is a pressure adjusting structure). An exhauster (which is an exhaust system or an exhaust structure) is constituted mainly by the exhaust pipe 231 and the APC valve 244. The exhauster may further include the vacuum pump 246.

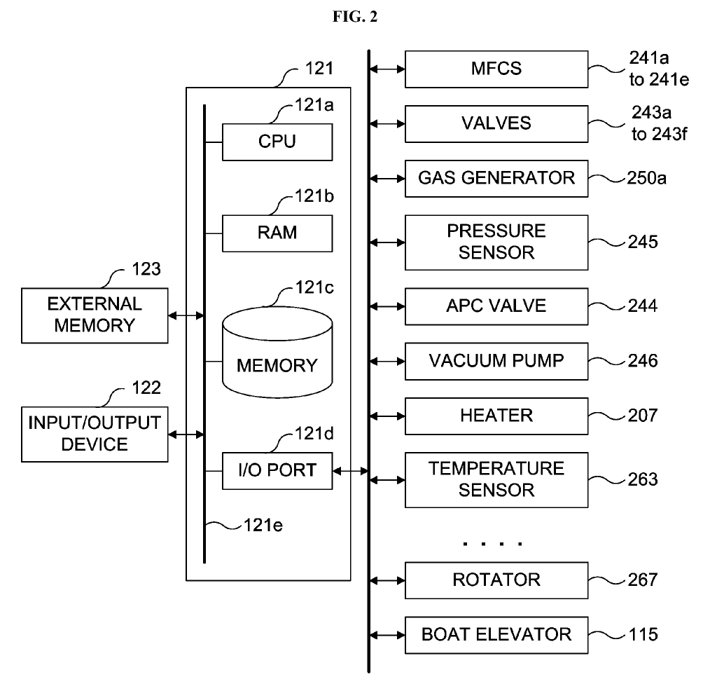

As shown in FIG. 2, a controller 121 serving as a control structure (control apparatus) is constituted by a computer including a CPU (Central Processing Unit) 121a, a RAM (Random Access Memory) 121b, a memory 121c and an I/O port (input/output port) 121d. The RAM 121b, the memory 121c and the I/O port 121d are configured to be capable of exchanging data with the CPU 121a through an internal bus 121e. For example, an input/output device 122 constituted by a component such as a touch panel is connected to the controller 121. In addition, the controller 121 is configured to be capable of being connected to an external memory 123. For example, as the control structure, the substrate processing apparatus may include a single control structure, or may include a plurality of control structures. That is, a control operation of performing a process sequence described later may be performed using the single control structure, or may be performed using the plurality of control structures. In addition, the plurality of control structures may be configured as a control system that are connected to one another via a wired or wireless communication network, and an entirety of the control system may perform the control operation of performing the process sequence described later. Thus, in the present specification, the term “control structure” may refer to the single control structure, may refer to the plurality of control structures, or may refer to the control system configured by the plurality of control structures.

For example, the memory 121c is configured by a component such as a flash memory, a hard disk drive (HDD) and a solid state drive (SSD). For example, a control program configured to control an operation of the substrate processing apparatus and a process recipe containing information on procedures and conditions of a substrate processing described later may be readably stored in the memory 121c. The process recipe is obtained by combining steps (procedures) of the substrate processing described later such that the controller 121 can execute the steps by the substrate processing apparatus to acquire a predetermined result, and functions as a program. Hereinafter, the process recipe and the control program may be collectively or individually referred to as a “program” or a “program product”. In addition, the process recipe may also be simply referred to as a “recipe”. Thus, in the present specification, the term “program” may refer to the recipe alone, may refer to the control program alone or may refer to both of the recipe and the control program. The RAM 121b functions as a memory area (work area) where a program or data read by the CPU 121a is temporarily stored.

The I/O port 121d is connected to the components described above such as the MFCs 241a to 241e, the valves 243a to 243f, the gas generator 250a, the pressure sensor 245, the APC valve 244, the vacuum pump 246, the temperature sensor 263, the heater 207, the rotator 267, the boat elevator 115 and a shutter opening/closing structure (not shown).

The CPU 121a is configured to read the control program from the memory 121c and execute the control program read from the memory 121c. In addition, the CPU 121a is configured to read the recipe from the memory 121c, for example, in accordance with an operation command inputted from the input/output device 122. In accordance with contents of the recipe read from the memory 121c, the CPU 121a may be configured to be capable of controlling various operations such as a gas generating operation by the gas generator 250a, flow rate adjusting operations for various substances (various gases) by the MFCs 241a to 241e, opening and closing operations of the valves 243a to 243f, an opening and closing operation of the APC valve 244, a pressure adjusting operation by the APC valve 244 based on the pressure sensor 245, a start and stop operation of the vacuum pump 246, a temperature adjusting operation by the heater 207 based on the temperature sensor 263, an operation of adjusting a rotation and a rotation speed of the boat 217 by the rotator 267, an elevating and lowering operation of the boat 217 by the boat elevator 115 and an opening and closing operation of a shutter (not shown) by the shutter opening/closing structure (not shown).

The controller 121 may be embodied by installing the above-described program written and stored in the external memory 123 into the computer. For example, the external memory 123 may include a magnetic disk such as a hard disk drive (HDD), an optical disk such as a compact disk (CD), a magneto-optical disk such as a magneto-optical disk (MO) and a semiconductor memory such as a USB memory and a solid state drive (SSD). The memory 121c or the external memory 123 may be embodied by a non-transitory computer readable recording medium. Hereafter, the memory 121c and the external memory 123 may be collectively or individually referred to as a “recording medium”. Thus, in the present specification, the term “recording medium” may refer to the memory 121c alone, may refer to the external memory 123 alone, or may refer to both of the memory 121c and the external memory 123. Instead of the external memory 123, a communication interface such as the Internet and a dedicated line may be used for providing the program to the computer.

### 2. Substrate Processing

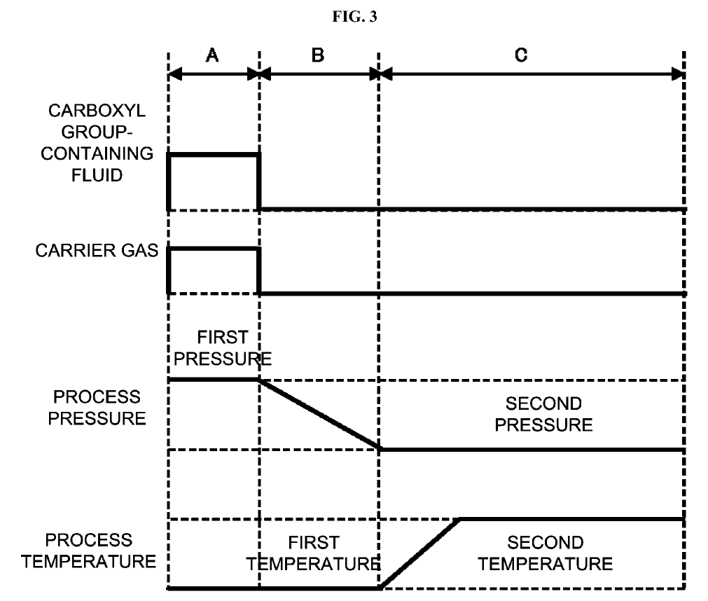

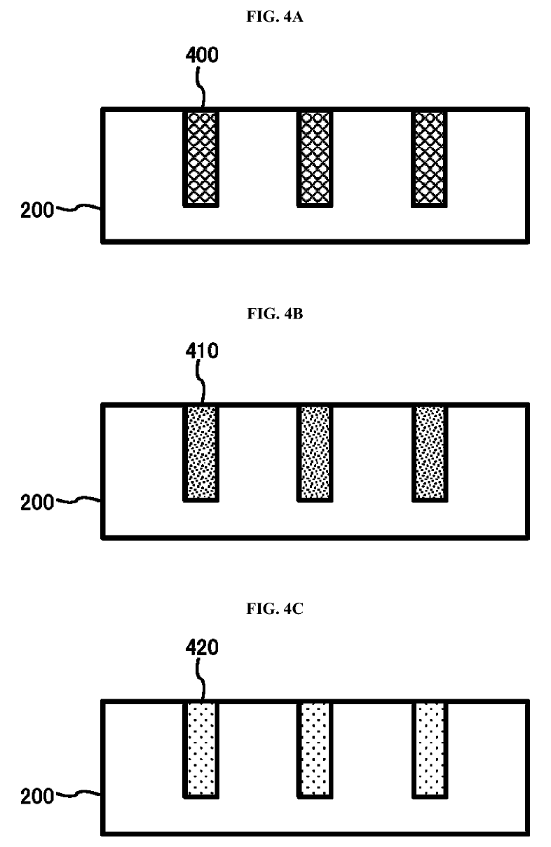

Hereinafter, a method of processing the substrate (which is a part of a manufacturing process of a semiconductor device by using the substrate processing apparatus described above), specifically, an example of the process sequence of processing the wafer 200 serving as the substrate with a metal-containing film 400 formed on a surface of the wafer 200, will be described mainly with reference to FIGS. 3 and 4A - 4C. The present embodiments will be described by way of an example in which the wafer 200 provided with a concave structure (also referred to as a “recess”) (that is, a three-dimensional structure such as a trench, a groove and a hole) formed on the surface thereof is used.

For example, in the present specification, the term “recess” is not limited to a structure provided with a bottom surface (lower surface), and may include a structure such as a through-hole and a gap provided without a bottom surface. When the structure is not provided with a “bottom surface”, the term “bottom side” (bottom location) may refer to a direction (location) from each of two or more openings of the structure toward an interior of the structure when viewed from each of the two or more openings.

For example, the present embodiments will be described by way of an example in which the metal-containing film 400 is formed as a wiring in the recess formed in the wafer 200 (see FIG. 4A). For example, the metal-containing film 400 is formed so as to fill the recess from an upper portion (opening location) to a lower portion (deep location or bottom location) of the recess. In addition, the present embodiments will be described by way of an example in which the metal-containing film 400 is exposed at the upper portion of the recess and provided with a structure including a plurality of crystal grains 300. In the following description, operations of components constituting the substrate processing apparatus are controlled by the controller 121.

In the process sequence according to the present embodiments, the following steps are performed:
(a) a step A of removing impurities 305 from the metal-containing film 400 by supplying the -COOH-containing fluid to the wafer 200 at a first temperature while maintaining the inner pressure of the process chamber 201 accommodating the wafer 200 provided with the metal-containing film 400 at a first pressure;
(b) a step B of setting the inner pressure of the process chamber 201 to a second pressure lower than the first pressure by exhausting the inner atmosphere of the process chamber 201 while stopping a supply of the -COOH-containing fluid; and
(c) a step C of increasing a crystal grain size (crystal grain diameter) (that is, a diameter of the crystal grains 310) of a metal component in a metal-containing film 410 by heating the wafer 200 to a second temperature higher than the first temperature while maintaining the inner pressure of the process chamber 201 at the second pressure and while exposing the metal-containing film 410 (from which the impurities 305 are removed).

According to the present embodiments, it is preferable that a cycle including the step A and the step B is performed one or more times before performing the step C. In the following example, as shown in FIG. 3, a case in which the steps A, B and the step C are performed in this order will be described.

In the following example, as shown in FIG. 3, a case in which a carrier gas for the -COOH-containing fluid is supplied in the step A and a supply of the carrier gas is stopped in the step B will be described. In addition, in FIG. 3, execution periods (time durations) during which the steps A, B and C are performed are represented as “A”, “B” and “C”, respectively.

For example, the impurities 305 contained in the metal-containing film 400 may include oxygen (O) which is absorbed through crystal grain boundaries (that is, boundaries between crystal grains) when the wafer 200 provided with the metal-containing film 400 is exposed to an air atmosphere. In addition, for example, the impurities 305 may include oxygen and carbon (C) contained in a residue of a plating solution used in an electroplating process performed to form the metal-containing film 400 in the recess of the wafer 200. Hereinafter, the present embodiments will be described by way of an example in which the impurities 305 contained in the metal-containing film 400 are oxygen.

In the present specification, the term “fluid” includes at least one among a gas, a liquid and a vapor. Hereinafter, the present embodiments will be described by way of an example in which the -COOH-containing fluid is a vaporized gas (gas or gaseous substance) obtained by vaporizing the first liquid described above.

In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. Thus, in the present specification, “forming a predetermined layer (or a film) on a wafer” may refer to “forming a predetermined layer (or a film) directly on a surface of a wafer itself”, or may refer to “forming a predetermined layer (or a film) on a surface of another layer (or another film) formed on a wafer”. In the present specification, the terms “substrate” and “wafer” and may be used as substantially the same meaning.

### Substrate Preparation Step

The plurality of wafers 200 provided with the metal-containing film 400 containing the impurities 305 are transferred (loaded) into the boat 217. Thereafter, as shown in FIG. 1, the boat 217 supporting the wafers 200 is elevated by the boat elevator 115 and loaded into the process chamber 201. In such a state, the seal cap 219 airtightly seals the lower end of the reaction tube 203.

### Pressure and Temperature Adjusting Step

The vacuum pump 246 vacuum-exhausts (decompresses and exhausts) the inner atmosphere of the process chamber 201 (that is, a space in which the wafers 200 are present (accommodated)) such that the inner pressure of the process chamber 201 reaches and is maintained at a desired pressure (vacuum degree). In such an operation, the inner pressure of the process chamber 201 is measured by the pressure sensor 245, and the APC valve 244 is feedback-controlled based on pressure information detected by the pressure sensor 245. In addition, the wafer 200 is heated by the heater 207 to a desired process temperature. In such an operation, a state of electric conduction to the heater 207 is feedback-controlled based on temperature information detected by the temperature sensor 263 such that a desired temperature distribution of a temperature (inner temperature) of the process chamber 201 can be obtained. In addition, a rotation of the wafer 200 is started by the rotator 267. The vacuum pump 246 continuously vacuum-exhausts the inner atmosphere of the process chamber 201, the heater 207 continuously heats the wafer 200 in the process chamber 201 and the rotator 267 continuously rotates the wafer 200 until at least a processing of the wafer 200 is completed.

### Preparation Step for Step A

In the step A, the gas generator 250a starts generating the vaporized gas to supply the -COOH-containing fluid to the wafer 200. According to the present embodiments, the -COOH-containing fluid (that is, the vaporized gas) is generated by vaporizing the first liquid.

Specifically, first, the valves 243c and 243d are opened to start a supply of the first liquid and a supply of the vaporization carrier gas to the gas generator 250a while controlling flow rates of the first liquid and the vaporization carrier gas by the MFCs 241c and 241d, respectively. Thereby, the gas generator 250a generates the vaporized gas of the first liquid (that is, the -COOH-containing fluid). In such an operation, the controller 121 controls the MFC 241c to adjust the flow rate and other parameters of the -COOH-containing fluid generated by the gas generator 250a. In addition, the first liquid stored in the tank 250t is forced out from the tank 250t into the supply pipe 232c by opening the valve 243e and supplying the pressurized gas to the tank 250t while controlling (or adjusting) a flow rate of the pressurized gas by the MFC 241e. The present step may be started during or before the pressure and temperature adjusting step mentioned above.

### Step A: Impurity Removing Process

In the present step, the -COOH-containing fluid is supplied to the metal-containing film 400 at the first temperature to remove the impurities 305 from the metal-containing film 400.

Specifically, the valve 243a is opened to supply the -COOH-containing fluid (which is generated in the gas generator 250a) into the process chamber 201 through the MFC 241a, the gas supply pipe 232a and the gas supply port 203p.

The -COOH-containing fluid supplied into the process chamber 201 flows downward within the process chamber 201, and is exhausted to an outside (outer portion) of the process chamber 201 through the exhaust pipe 231. Thereby, the -COOH-containing fluid is supplied to the wafer 200. In such an operation, the valve 243b is opened to supply the inert gas into the process chamber 201 through the gas supply pipes 232b and 232a and the gas supply port 203p while controlling a flow rate of the inert gas by the MFC 241b. The inert gas acts as the carrier gas for the -COOH-containing fluid.

For example, process conditions when supplying the -COOH-containing fluid in the present step are as follows:
A process temperature (first temperature): from 80° C. to 120° C., preferably from 90° C. to 100° C.;
A process pressure (first pressure): from 700 hPa to 1,400 hPa, preferably from 800 hPa to 1,100 hPa;
A supply flow rate of the -COOH-containing fluid: from 5 ccm to 400 ccm, preferably from 50 ccm to 300 ccm;
A supply time (time duration) of supplying the -COOH-containing fluid: from 10 minutes to 120 minutes, preferably from 30 minutes to 60 minutes;
A supply flow rate of the vaporization carrier gas: from 0.5 slm to 10 slm, preferably from 1 slm to 5 slm; and
A supply flow rate of the carrier gas (inert gas): from 1 slm to 10 slm.
It is preferable that the process temperature (first temperature) in the present step is set to a temperature at which the -COOH-containing fluid does not liquefy.

In the present specification, a notation of a numerical range such as “from 80° C. to 120° C.” means that a lower limit and an upper limit thereof are included in the numerical range. Therefore, for example, the numerical range “from 80° C. to 120° C.” means a range equal to or higher than 80° C. and equal to or lower than 120° C. The same also applies to other numerical ranges described herein. In addition, in the present specification, the term “process temperature” may refer to the temperature of the wafer 200 or may refer to the inner temperature of the process chamber 201, and the term “process pressure” may refer to the inner pressure of the process chamber 201, in other words, a pressure (inner pressure) of the space in which the wafers 200 are present. In addition, the term “process time” refers to a time duration of continuously performing a process related thereto. In addition, when a supply flow rate of a substance (gas) includes “0 ccm”, it refers to a case where the substance (gas) is not supplied. The same also applies to the following description.

By supplying the -COOH-containing fluid to the wafer 200 under the process conditions mentioned above, it is possible to modify the metal-containing film 400 into the metal-containing film 410 (see FIGS. 4A and 4B). Specifically, it is possible to remove the impurities 305 from the metal-containing film 400 formed on the wafer 200. More specifically, by supplying the -COOH-containing fluid serving as a reducing agent to the wafer 200 under the process conditions mentioned above, for example, an oxygen component present in the metal-containing film 400 (for example, at the crystal grain boundaries) can be reacted with a component in the -COOH-containing fluid penetrating into the metal-containing film 400. Thereby, it is possible to desorb (remove) the oxygen component from an inside (inner portion) of the metal-containing film 400. The impurities removed from the metal-containing film 400 may diffuse into the process chamber 201.

By supplying the -COOH-containing fluid to the wafer 200 under the process conditions mentioned above, it is possible for the -COOH-containing fluid to permeate an entirety of the metal-containing film 400, specifically from the upper portion to the lower portion of the recess.

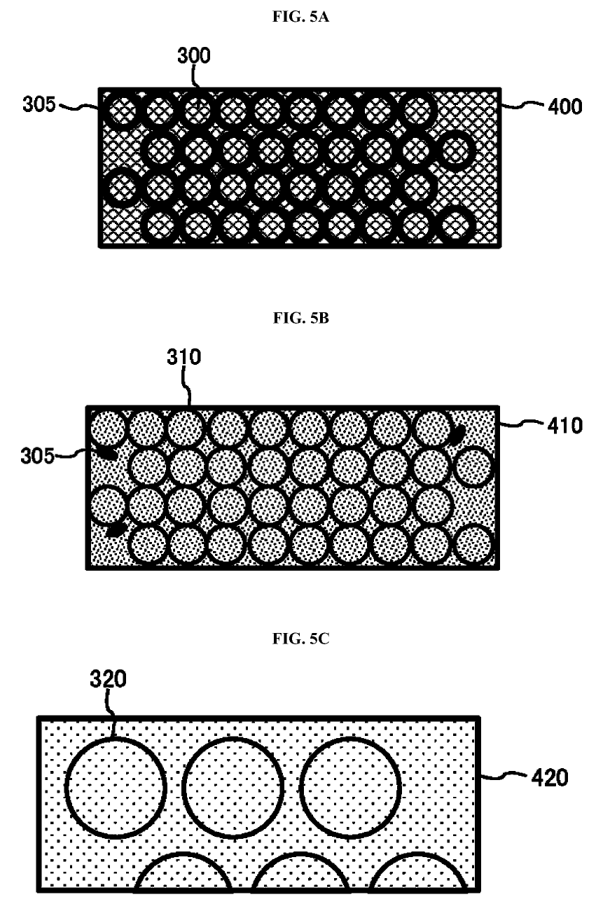

By supplying the -COOH-containing fluid to the wafer 200 under the process conditions mentioned above, specifically by setting the process temperature (first temperature) to a relatively low temperature, it is possible to maintain the diameter of the crystal grains 310 (size of the crystal grains 310) contained in the metal-containing film 410 at a predetermined value or less (see FIGS. 5A and 5B). In such an operation, at each of the upper portion and the lower portion of the recess, specifically from the upper portion to the lower portion of the recess, it is possible to maintain the diameter of the crystal grains 310 at the predetermined value or less. By maintaining the diameter of the crystal grains 310 at the predetermined value or less in a manner described above, it is possible to maintain a grain boundary energy (between adjacent crystal grains among the crystal grains 310) at a high level.

When the process temperature is set to be lower than 80° C., the -COOH-containing fluid may be condensed within the process chamber 201. In such a case, the -COOH-containing fluid may not permeate the entirety of the metal-containing film 400. As a result, it may be difficult to remove the impurities 305 from the metal-containing film 400. By setting the process temperature to 80° C. or higher, it is possible to prevent the -COOH-containing fluid from condensing, and it is also possible for the -COOH-containing fluid to permeate the entirety of the metal-containing film 400. As a result, it is possible to remove the impurities 305 from the metal-containing film 400.

When the process temperature is set to be higher than 120° C., a crystallization rate of the metal-containing film 400 may be greater than a rate (that is, an impurity removal rate) at which the impurities 305 contained in the metal-containing film 400 are removed. Specifically, for example, the diameter of the crystal grains 300 contained in the metal-containing film 400 may become larger than a predetermined value before the impurities 305 are removed from the metal-containing film 400 and a concentration of the impurities 305 reaches a desired concentration. As a result, it may be difficult to maintain the grain boundary energy (between adjacent crystal grains among the crystal grains 300) at a high level. By setting the process temperature to 120° C. or lower, it is possible to set the impurity removal rate to be greater than the crystallization rate of the metal-containing film 400. That is, it is possible to adjust the concentration of the impurities 305 in the metal-containing film 400 to the desired concentration before the diameter of the crystal grains 300 become larger than the predetermined value. As a result, it is possible to remove the impurities 305 from the metal-containing film 400 and it is also possible to maintain the grain boundary energy (between adjacent crystal grains among the crystal grains 300) at a high level before the diameter of the crystal grains 300 contained in the metal-containing film 400 becomes larger than the predetermined value.

As described above, the step A may be started with the wafer 200 already maintained at the first temperature. Alternatively, the step A may be performed while the wafer 200 (which is at a temperature lower than the first temperature) is being heated to the first temperature. In such a case, it is preferable to heat the wafer 200 at a relatively slow rate (for example, a rate slower than a rate at which the wafer 200 is heated from the first temperature to the second temperature in a step c1 described below; hereinafter, such a rate may also be referred to as a “first heating rate” or a “first temperature elevating rate”). When the temperature of wafer 200 is increased too rapidly, the crystallization rate of the metal-containing film 400 may be greater than the rate (that is, the impurity removal rate) at which the impurities 305 contained in the metal-containing film 400 are removed. By heating wafer 200 at the first heating rate, it is possible to remove the impurities 305 from the metal-containing film 400 before the diameter of the crystal grains exceeds a predetermined value. Therefore, since the impurities 305 do not hinder the crystallization, it is possible to increase the crystal grain size as compared with a case in which the temperature of wafer 200 is increased too rapidly.

As the first liquid, for example, a liquid containing -COOH, such as formic acid (HCOOH) and acetic acid (CH₃COOH) may be used. For example, the -COOH-containing fluid (that is, the vaporized gas of the HCOOH or the CH₃COOH) acts as the reducing agent capable of removing the impurities 305 (for example, the oxygen component) from the metal-containing film 400. As the first liquid, it is preferable to use a liquid containing HCOOH, which has a higher reducing power. Because -COOH contains carbon, oxygen and hydrogen (H), the -COOH-containing fluid may also be referred to as a fluid containing carbon, oxygen and hydrogen. Similarly, a -COOH-containing gas may also be referred to as a gas containing carbon, oxygen and hydrogen.

In the present specification, the term “agent” may contain at least one selected from the group of a gaseous substance and a liquid substance. The liquid substance may contain a mist substance. In other words, the reducing agent may contain a gaseous substance, may contain a liquid substance such as a mist substance, or may contain both of the gaseous substance and the liquid substance.

As the carrier gas (inert gas), for example, nitrogen (N₂) gas or a rare gas such as argon (Ar) gas, helium (He) gas, neon (Ne) gas and xenon (Xe) gas may be used. As the inert gas, for example, one or more of the gases exemplified above may be used. The same also applies to each step described below.

As the vaporization carrier gas, for example, a gas similar to the inert gas described above may be used.

### Step B: Process of Exhausting Inner Atmosphere of Process Chamber

After a predetermined time has elapsed and the impurities 305 are removed from the metal-containing film 400, the valves 243a and 243b are closed to stop the supply of the -COOH-containing fluid and the supply of the carrier gas to the wafer 200. Then, by exhausting (vacuum-exhausting) the inner atmosphere of the process chamber 201, it is possible to remove a substance (such as a fluid and reaction by-products remaining in the process chamber 201) from the process chamber 201.

For example, process conditions when vacuum-exhausting the inner atmosphere of the process chamber 201 in the present step are as follows:
A process temperature (first temperature): from 80°C to 120° C., preferably from 90° C. to 100° C.;
A process pressure (the second pressure lower than the first pressure): from 100 hPa to 3,000 hPa; and
A process time: from 5 minutes to 60 minutes, preferably from 5 minutes to 10 minutes.
As described above, the process pressure (second pressure) in the step B is lower than the process pressure (first pressure) in the step A. Therefore, an exhaust flow rate out of the process chamber 201 in the step B can be greater than an exhaust flow rate out of the process chamber 201 in the step A.

By exhausting the inner atmosphere of the process chamber 201 under the process conditions mentioned above, it is possible to discharge (or exhaust) substances (hereinafter, collectively and simply referred to as “impurities”) such as the impurities 305 floating or adhering in the process chamber 201 (specifically, an inner space and an inner wall of the process chamber 201), intermediates of the -COOH-containing fluid or the carrier gas for the -COOH-containing fluid, a native oxide film (which is formed on the surface of the wafer 200 when the wafer 200 is transferred into the process chamber 201) and the like out of the process chamber 201.

### Step C: Heating Process and Annealing Process

After the step B is completed, while exposing the metal-containing film 410 (from which the impurities 305 are removed), the wafer 200 is heated (annealed) to the second temperature higher than the first temperature. For example, the present step is performed by sequentially performing steps c1 and c2 described below.

### Step c1: Heating Step

In the present step, an annealing process is performed while increasing (or elevating) a temperature of the metal-containing film 410 from the first temperature to the second temperature by adjusting an output of the heater 207.

For example, process conditions when performing the annealing process while increasing the temperature of the metal-containing film 410 in the present step are as follows:
A process pressure (second pressure): from 100 hPa to 3,000 hPa; and
A process time: from 20 minutes to 40 minutes, preferably from 25 minutes to 35 minutes.
A reduced pressure state (second pressure) of the step B is maintained in the present step.

Preferably, a second heating rate (second temperature elevating rate) in the step c1 is set to be greater than the first heating rate mentioned above. When the wafer 200 is heated gradually in the step c1, it is likely that many of the crystal grains in the metal-containing film 400 simultaneously and gradually grow. In such a case, since the number of the crystal grains of a similar size increases, as a result, the crystal grain size may not become a desired size. On the other hand, when the wafer 200 is heated suddenly, for example, at the second heating rate greater than the first heating rate, some of the crystal grains may grow in size in response to a temperature increase, while others of the crystal grains may not grow in size in response to the temperature increase. Therefore, the former crystal grains (which grow in size) can grow without being hindered by the impurities or by surrounding crystal grains. Therefore, by heating the wafer 200 at the second heating rate, it is possible to produce the crystal grains with a larger grain size as compared with a case in which the wafer 200 is heated gradually.

### Step c2: Temperature Maintaining Step

When the temperature of the metal-containing film 410 reaches and is maintained at the second temperature, the annealing process is performed while maintaining the metal-containing film 410 (specifically, a metal-containing film 420) at the second temperature (see FIGS. 5B and 5C).

For example, process conditions when performing the annealing process while maintaining the metal-containing film 420 at the second temperature in the present step are as follows:
A process temperature (second temperature): from 150° C. to 400° C., preferably from 160° C. to 300° C.;
A process pressure (second pressure): from 100 hPa to 3,000 hPa; and
A process time: from 30 minutes to 300 minutes, preferably from 60 minutes to 180 minutes.

By increasing the process temperature (specifically, the temperature of the metal-containing film 410) from the first temperature to the second temperature under the process conditions mentioned above and maintaining the process temperature at the second temperature, it is possible to modify the metal-containing film 410 into the metal-containing film 420 (see FIGS. 4B and 4C). Specifically, it is possible to grow the crystal grains 310 contained in the metal-containing film 410 into crystal grains 320 whose diameter is greater than that of the crystal grains 310 (see FIGS. 5B and 5C). In a manner described above, it is possible to set (or adjust) the diameter (crystal grain size) of the crystal grains 320 of the metal component in the metal-containing film 420 in the present step to be greater (larger) than the diameter (crystal grain size) of the crystal grains 310 in the metal-containing film 410 in the step B.

By increasing the process temperature from the first temperature to the second temperature under the process conditions mentioned above and maintaining the process temperature at the second temperature, it is possible to set (or adjust) the diameter of the crystal grains 320 contained in the metal-containing film 420 to be greater than a predetermined value (see FIG. 5C). In such an operation, at each of the upper portion and the lower portion of the recess, specifically from the upper portion to the lower portion of the recess, it is possible to set (or adjust) the diameter of the crystal grains 320 to a desired value greater than the predetermined value.

By increasing the process temperature from the first temperature to the second temperature under the process conditions mentioned above and maintaining the process temperature at the second temperature, it is also possible to remove the impurities 305 (which are not removed in the step B) remaining in the metal-containing film 410 (see FIGS. 5B and 5C). In the present step, the reduced pressure state (second pressure) of the step B is maintained. Therefore, in addition to the impurities 305 removed from the metal-containing film 410, it is also possible to discharge the impurities such as intermediates (which are not discharged in the step B) of the -COOH-containing fluid from the process chamber 201.

In addition, by increasing the process temperature from the first temperature to the second temperature under the above conditions and maintaining the process temperature at the second temperature, it is possible to set growth rates of adjacent crystal grains (among the crystal grains 310) to be different from each other. In such a manner, by performing the heating process under conditions where the crystal grains 310 can grow selectively, the crystal grains 310 (which grow more predominantly) grow preferentially. Thereby, it is possible to form the crystal grains 320 with larger diameters. As a result, it is possible to increase the diameter of crystal grains 320 in the metal-containing film 420.

As described above, by setting the diameter of crystal grains 320 to be greater than the diameter of the crystal grains 310, the number of the crystal grain boundaries per unit volume in the metal-containing film 420 becomes smaller than the number of the crystal grain boundaries per unit volume in the metal-containing film 410. Therefore, the grain boundary energy between adjacent crystal grains among the crystal grains 320 in the step C is lower than the grain boundary energy between adjacent crystal grains among the crystal grains 310 in the step B.

When the process temperature is set to be lower than 150° C., it may be difficult to crystallize the metal-containing film 410. Thereby, the diameter of the crystal grains 320 may be suppressed from increasing. In addition, when the process temperature is set to be lower than 150° C., condensation droplets may remain in the process chamber 201. Thereby, a vacuum exhaust process of exhausting the inner atmosphere of the process chamber 201 may be performed after the step C is completed. By setting the process temperature to 150° C. or higher, the metal-containing film 410 can be crystallized, thereby making it possible to increase the diameter of the crystal grains 320 as desired. Further, by setting the process temperature to 150° C. or higher, it is possible to prevent (or suppress) the condensation droplets from remaining in the process chamber 201. Thereby, it is possible to omit the vacuum exhaust process after the step C is completed.

When the process temperature is set to be higher than 400° C., the diameter of the crystal grains 320 may become too large. Thereby, a void or the like may be generated in the metal-containing film 420. By setting the process temperature to 400° C. or lower, it is possible to prevent (or suppress) the diameter of the crystal grains 320 from becoming too large. Thereby, it is possible to form the metal-containing film 420 with an excellent quality and free of the void.

### Returning to Atmospheric Pressure Step

Then, the inner atmosphere of the process chamber 201 is vacuum-exhausted by the vacuum pump 246. Then, by returning the inner pressure of the process chamber 201 to the atmospheric pressure by supplying the inert gas thereinto, it is possible to increase a heat capacity in the process chamber 201. Thereby, it is possible to uniformly heat the wafer 200 and components (structures) in the process chamber 201, and it is also possible to remove substances (such as particles, the impurities 305 and an out gas that cannot be removed by vacuum-exhausting the process chamber 201) from the process chamber 201. After a predetermined time has elapsed, the inner temperature of the process chamber 201 is lowered to a predetermined temperature at which the substrate (that is, the wafer 200) can be unloaded from the process chamber 201.

### Substrate Unloading Step

The seal cap 219 is lowered by the boat elevator 115 and the lower end of the reaction tube 203 is opened. Then, the boat 217 accommodating the wafers 200 (which are processed) is unloaded out of the reaction tube 203 through the lower end opening of the reaction tube 203. After the boat 217 is unloaded out of the reaction tube 203, the wafers 200 (which are processed) are transferred (discharged) out of the boat 217.

### 3. Effects According to Present Embodiments

According to the present embodiments, it is possible to obtain one or more of the effects described below.

(a) By performing the steps A, B and C, it is possible to reduce the resistivity of the metal-containing film 420. Hereinafter, details thereof will be described.

By setting the temperature (process temperature) of the wafer 200 to the first temperature (which is relatively low) in the step A, it is possible to remove the impurities 305 from the metal-containing film 400 while suppressing a growth of the crystal grains 300 in the metal-containing film 400. In a manner described above, by setting the process temperature to the first temperature (which is relatively low) in the step A, it is possible to suppress the growth of the crystal grains 300 in the metal-containing film 400, and it is also possible to maintain the diameter of the crystal grains 310 (after the growth) at a predetermined value or less (see FIGS. 5A and 5B). As a result, it is possible to prevent a decrease in the number of the crystal grain boundaries per unit volume in the metal-containing film 410. Thereby, it is possible to maintain the grain boundary energy at a high level. As a result, since a speed of an atomic movement (that is, an atomic migration rate) can be increased in the step C, it is possible to increase the diameter of the crystal grains 320. In addition, in the step B, by removing the impurities 305 (specifically, the impurities 305 present at the crystal grain boundaries) in the metal-containing film 400, it is possible to increase the grain boundary energy. As a result, since the atomic migration rate in the step C can be increased, it is possible to increase the diameter of the crystal grains 320.

By performing the heating process (annealing process) on the wafer 200 at the second temperature higher than the first temperature in the step C, it is possible to increase the diameter of the crystal grains 320.

In addition, after the step A is completed, the impurities may float in the inner space of the process chamber 201 or may adhere to the inner wall of the process chamber 201. As described above, for example, the impurities may include the native oxide film (for example, the oxygen component) formed on the surface of the wafer 200 when the wafer 200 is transferred into the process chamber 201, the impurities 305 (for example, the oxygen component) removed from the metal-containing film 400, the intermediates (for example, a carbon component) of the -COOH-containing fluid supplied in the step A, and components of the carrier gas (for example, a nitrogen component). When the step C is performed in such a state, the impurities permeate the metal-containing film 420. In such a case, there is a concern that the diameter (crystal grain size) of the crystal grains 320 of the metal component in the metal-containing film 420 may be inhibited from increasing.

According to the embodiments of the present disclosure, after the step A is completed and before the step C is started, the step B is performed to exhaust the inner atmosphere of the process chamber 201 such that impurities remaining in the process chamber 201 can be discharged out of the process chamber 201. Thereby, in the step C, it is possible to suppress a permeation of the impurities, which prevent (or inhibit) the diameter of the crystal grains 320 from increasing, into the metal-containing film 420.

In addition, since the reduced pressure state (second pressure) in the step B is maintained in the step C, the impurities 305 removed from the metal-containing film 410 during an execution of the step C or the impurities remaining in the process chamber 201 can be discharged out of the process chamber 201. Thereby, in the step C, it is possible to suppress the permeation of the impurities, which prevent the diameter of the crystal grains 320 from increasing, into the metal-containing film 420.

When increasing the diameter of the crystal grains 320 in the step C, the number of the crystal grain boundaries per unit volume in the metal-containing film 420 is reduced. Thereby, electron scattering at the crystal grain boundaries is also reduced. Therefore, electrons flow more easily through the metal-containing film 420, and thereby, the resistivity of the metal-containing film 420 may be reduced. As a result, it is possible to improve device characteristics.
(b) In the step C, after stopping the supply of the -COOH-containing fluid in the step A, the heating step (heating process) of increasing the temperature of the wafer 200 from the first temperature to the second temperature is started. Thereby, in the step C, it is possible to crystallize the metal-containing film 410 while suppressing an additional penetration of the intermediates of the -COOH-containing fluid. As a result, it is possible to effectively increase the diameter of the crystal grains 320 of the metal component.
(c) In the step C, after the process of exhausting the inner atmosphere of the process chamber 201 in the step B is completed, the heating process of increasing the temperature of the wafer 200 from the first temperature to the second temperature is started. Thereby, it is possible to crystallize the metal-containing film 410 after the impurities remaining in the process chamber 201 are discharged out of the process chamber 201. As a result, it is possible to effectively increase the diameter of the crystal grains 320 of the metal component while suppressing an influence of the impurities.
(d) By supplying the carrier gas for the -COOH-containing fluid in the step A, it is possible for the -COOH-containing fluid to permeate the entirety of the metal-containing film 400. Thereby, it is possible to effectively remove the impurities 305 from the metal-containing film 400. In the step B, by stopping the supply of the carrier gas and exhausting (vacuum-exhausting) the inner atmosphere of the process chamber 201 so as to set the process chamber 201 in the reduced pressure state (second pressure), it is possible to effectively discharge the impurities remaining in the process chamber 201. In addition, since the reduced pressure state (second pressure) is maintained in the step C, it is possible to prevent the impurities from remaining in the process chamber 201. As a result, since the vacuum exhaust process after the step C is completed can be omitted, it is possible to improve the throughput.
(e) The second temperature is set to the temperature at which the diameter of the crystal grains 320 becomes the desired value. Thereby, it is possible to grow the diameter of the crystal grains 320 to the desired value in the step C. As a result, it is possible to effectively reduce the resistivity of the metal-containing film 420. In addition, by setting the second temperature to the temperature at which the diameter of the crystal grains 320 becomes the desired value, it is possible to prevent an excessive growth of the diameter of the crystal grains 320 in the step C. Thereby, it possible to suppress an occurrence of the void and the like in the metal-containing film 420.
(f) An amount of the impurities present in the process chamber 201 after the step B is completed is less than an amount of the impurities present in the process chamber 201 after the step A is completed. As a result, by reducing the amount of the impurities in the step C, it is possible to suppress the influence of the impurities when the diameter of the crystal grains 320 is increased. Therefore, it is possible to more reliably increase the diameter of the crystal grains 320.
(g) The process temperature (first temperature) in the step A is set to the temperature at which the -COOH-containing fluid does not liquefy. Thereby, it is possible to suppress an adhesion of the -COOH-containing fluid (which is liquefied) to the inner wall of the process chamber 201 and the like in the step A. As a result, in the step C, since a liquefied component of the -COOH-containing fluid (for example, the carbon component) can be prevented from permeating the metal-containing film 420, it is possible to increase the diameter of the crystal grains 320.
(h) The exhaust flow rate out of the process chamber 201 in the step B is set to be greater than the exhaust flow rate out of the process chamber 201 in the step A. Thereby, it is possible to reliably obtain the effects mentioned above.
(i) The heating rate in the step C (that is, the second heating rate) is set to greater than the heating rate in the step A (that is, the first heating rate). In the step C (in which the temperature is increased at a relatively rapid rate), some of the crystal grains may easily grow in size in response to the temperature increase, while others of the crystal grains may not easily grow in size in response to the temperature increase. The crystal grains that grow more rapidly can coarsen without being hindered by the impurities or the surrounding crystals. As a result, it is possible to easily form the crystal grains 320 with larger diameters.
(j) In the step C, by heating the wafer 200 such that the growth rates of adjacent crystal grains (among the crystal grains 310) are different, it is possible to preferentially grow the crystal grains 310 that grow more rapidly. As a result, it is possible to easily form the crystal grains 320 with larger diameters.
(k) By performing the step C after the step A and the step B are performed, it is possible to promote a selective crystal grain growth in a state where the impurities are reduced. As a result, it is possible to more stably form the crystal grains 320 with larger diameters.
( l ) When using the -COOH-containing fluid mentioned above and/or the various inert gases mentioned above, it is possible to obtain substantially the same effects mentioned above.

### Another Embodiment of Present Disclosure

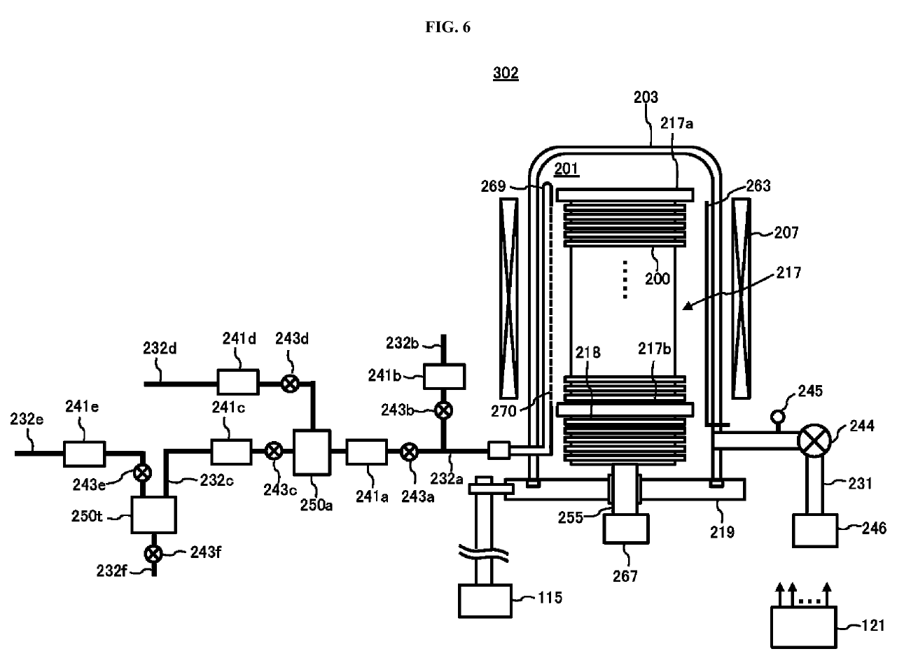

For example, the embodiments mentioned above are described by way of an example in which the fluid is supplied to the wafer 200 through an upper portion of the wafer accommodation region. However, the technique of the present disclosure is not limited thereto. For example, the fluid may be supplied to the wafer 200 through a side portion of the wafer accommodation region, using a substrate processing apparatus shown in FIG. 6.

FIG. 6 is a diagram schematically illustrating a vertical cross-section of a process furnace (vertical type process furnace) 302 of a substrate processing apparatus in which the fluid is supplied to the process chamber 201 using a nozzle 269 instead of the gas supply port 203p. As shown in FIG. 6, the nozzle 269 is installed in a space between the inner wall of the reaction tube 203 and the wafers 200, and extends upward in an arrangement direction of the wafers 200 from a lower portion to an upper portion of the inner wall of the reaction tube 203. A plurality of gas supply holes 270 (through which the fluid is supplied along an outer peripheral direction of the wafer 200, that is, through which the fluid is supplied from an edge of the wafer 200 to a center of the wafer 200) are provided at a side surface of the nozzle 269. The plurality of gas supply holes 270 are provided from the lower portion to the upper portion of the reaction tube 203, at positions facing the wafer accommodation region (wafer arrangement region). The nozzle 269 is connected to the gas supply pipe 232a. The fluid is supplied from the gas supply pipe 232a to the process chamber 201 through the nozzle 269. A -COOH-containing fluid supplier (which is a -COOH-containing fluid supply system or a -COOH-containing fluid supply structure) is constituted mainly by the gas supply pipe 232a, the MFC 241a and valve 243a. The -COOH-containing fluid supplier may further include the nozzle 269. The other components of the substrate processing apparatus shown in FIG. 6 are similar to the other components of the substrate processing apparatus shown in FIG. 1. Thus, substantially the same components shown in FIG. 6 as those of the substrate processing apparatus shown in FIG. 1 will be denoted by like reference numerals, and detailed descriptions thereof will be omitted.

Even when using the substrate processing apparatus with such a configuration shown in FIG. 6, it is possible to obtain substantially the same effects as in the embodiments mentioned above.

In addition, according to the present embodiment, unlike the substrate processing apparatus shown in FIG. 1, it is possible to reduce a distance between the wafer 200 and a gas supply hole (among the plurality of gas supply holes 270) corresponding thereto not only in the upper portion but also in a middle portion and a lower portion of the wafer accommodation region, and it is also possible to uniformize supply conditions (such as a flow rate and a flow velocity) of the fluid and the inert gas to the wafers 200 throughout the wafer accommodation region from its upper portion to its lower portion. As a result, in the step B, the fluid is supplied to the wafers 200 under uniform conditions throughout an entirety of the wafer accommodation region, that is, from the upper portion to the lower portion of the wafer accommodation region. Thereby, it is possible to improve a uniformity of an effect of removing the impurities between the wafers 200 when the impurities are removed from the metal-containing film. In addition, in a purge step (such as the step B) and/or the step C, the inert gas is supplied to the wafers 200 under uniform conditions throughout the entirety of the wafer accommodation region, that is, from the upper portion to the lower portion of the wafer accommodation region. Thereby, it is possible to improve a uniformity of each process between the wafers 200 when performing the process (such as a process of removing a residual substance and a film modification process) in each step.

For example, when the metal contained in the metal-containing film is a metal which is less prone to migration than copper (Cu) (for example, cobalt (Co), ruthenium (Ru) or tungsten (W)), the process temperature in the step B may be preferably set to a high temperature higher than 150° C. Under such a temperature condition, the fluid is more likely to be thermally decomposed. Thus, when the fluid is supplied through the upper portion of the wafer accommodation region using the substrate processing apparatus shown in FIG. 1, the uniformity of the effect of removing the impurities may become non-uniform between the upper portion and the lower portion of the wafer accommodation region. However, when the fluid is supplied through the side portion of the wafer accommodation region using the substrate processing apparatus shown in FIG. 6, such problems specific to the high temperature are less likely to occur.

For example, when the steps A, B and C are performed consecutively in the same process chamber in the embodiments mentioned above, it is preferable to perform the step B. As a result, it is possible to reliably remove the impurities (which are generated in the step A) by performing the step B. It is also possible to prevent the impurities generated in the step C from adhering to the wafer 200 in the step C.

For example, the embodiments mentioned above are described by way of an example in which each of the steps A, B and C is performed once. However, the technique of the present disclosure is not limited thereto. For example, the step C may be performed after a combination of the steps A and B is performed two or more times. By repeatedly performing the combination of the steps A and B in such a manner, it is possible to more reliably remove the impurities. In addition, since the step C is performed thereafter, it is possible to increase the crystal grain size in the absence of the impurities. In other words, it is possible to more reliably increase the crystal grain size.

For example, the embodiments mentioned above are described by way of the example in which each of the steps A, B and C is performed once. However, the technique of the present disclosure is not limited thereto. For example, a combination of the steps A, B and C may be performed two or more times. By repeatedly performing the combination of the steps A, B and C in such a manner, it is possible to repeatedly increase the crystal grain size in a state where the impurities is removed from the metal film. Therefore, it is possible to more reliably increase the crystal grain size.

### Other Embodiments of Present Disclosure

The technique of the present disclosure is described in detail by way of the embodiments mentioned above. However, the technique of the present disclosure is not limited thereto. The technique of the present disclosure may be modified in various ways without departing from the scope thereof.

For example, the embodiments mentioned above are described by way of an example in which the -COOH-containing fluid is the gaseous substance. However, the technique of the present disclosure is not limited thereto. For example, the -COOH-containing fluid may be a vapor or a liquid. In such a modified example, it is possible to obtain at least some of the effects of the embodiments mentioned above.

Although not described in the embodiments mentioned above, as the metal-containing film 400, for example, a film such as a copper-containing film, a cobalt-containing film, a tungsten-containing film and a ruthenium-containing film may be used. As the metal-containing film 400, for example, one or more of the films exemplified above may be used. In other words, as the metal material (metal component) constituting the metal-containing film 400, for example, a metal element such as Cu, Co, W and Ru may be used. In such a modified example, it is possible to obtain substantially the same effects as in the embodiments mentioned above.

For example, the embodiments mentioned above are described by way of an example in which the supply of the carrier gas is stopped in the step B. However, the technique of the present disclosure is not limited thereto. For example, a supply amount of the carrier gas may be reduced in the step B. In such a modified example, it is possible to obtain substantially the same effects as in the embodiments mentioned above.

Although not described in the embodiments mentioned above, for example, when a silicon (Si)-based film (for example, a silicon oxide (SiO) film) is formed as a base layer on an inner surface of the recess formed in the wafer 200, it is preferable to form a liner film between the metal-containing film 400 and the SiO film to prevent a metal atom contained in the metal-containing film 400 from diffusing into the SiO film.

For example, the embodiments mentioned above are described by way of an example in which the substrate processing apparatus includes a single process chamber (that is, the process chamber 201), and the steps A, B and C are performed within the process chamber 201. However, the technique of the present disclosure is not limited thereto. For example, the substrate processing apparatus may include a plurality of process chambers (also simply referred to as “chambers”), and each of the steps A, B and C may be performed within a different chamber. However, in such a case, the impurities 305 may permeate the wafer 200 since the wafer 200 is exposed to the air atmosphere when the wafer 200 is transferred to a chamber where the step B is to be performed after the step A is completed or when the wafer 200 is transferred to a chamber where the step C is to be performed after the step B is completed. In such cases, it is preferable to perform a step of removing the impurities 305 from the wafer 200 before starting the step B and before starting the step C.

It is preferable that recipes used in each process are prepared individually in accordance with contents of each process and stored in the memory 121c via an electric communication line or the external memory 123. When starting each process, it is preferable that the CPU 121a selects an appropriate recipe among the recipes stored in the memory 121c in accordance with the contents of each process. Thus, various films of different composition ratios, qualities and thicknesses can be formed in a reliably reproducible manner by using the single substrate processing apparatus. In addition, since the burden on an operator (operating personnel) can be reduced, various processes can be started quickly while avoiding an error in operating the substrate processing apparatus.

The recipe described above is not limited to creating a new recipe. For example, the recipe may be prepared by changing an existing recipe installed in the substrate processing apparatus in advance. When changing the existing recipe to a new recipe, the new recipe may be installed in the substrate processing apparatus via the electric communication line or a recording medium in which the new recipe is stored. Further, the existing recipe already stored in the substrate processing apparatus may be directly changed to the new recipe by operating the input/output device 122 of the substrate processing apparatus.

For example, the embodiments mentioned above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of processing one or several substrates at once is used to form the film. For example, the embodiments mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process procedures and the process conditions of each process using the substrate processing apparatuses mentioned above may be substantially the same as those of the embodiments or the modified examples mentioned above. Even in such a case, it is possible to obtain substantially the same effects as in the embodiments or the modified examples mentioned above.

In addition, the embodiments and the modified examples mentioned above may be appropriately combined. The process procedures and the process conditions of each combination thereof may be substantially the same as those of the embodiments mentioned above.

As described above, according to some embodiments of the present disclosure, it is possible to control the quality of the metal-containing film formed on the substrate.

What is claimed is:

1. A substrate processing method comprising:
(a) removing impurities from a metal-containing film by supplying a carboxyl group-containing fluid to a substrate provided with the metal-containing film at a first pressure and a first temperature;
(b) setting a pressure applied to the substrate to a second pressure lower than the first pressure by exhausting an atmosphere around the substrate while stopping a supply of the carboxyl group-containing fluid; and
(c) increasing a crystal grain size of a metal component in the metal-containing film by heating the substrate to a second temperature higher than the first temperature while setting the pressure applied to the substrate to the second pressure and while exposing the metal-containing film from which the impurities are removed.

2. The substrate processing method of claim 1, wherein, in (c), after stopping the supply of the carboxyl group-containing fluid in (a), a heating process of increasing a temperature of the substrate from the first temperature to the second temperature is started.

3. The substrate processing method of claim 1, wherein, in (c), after a process of exhausting the atmosphere in (b) is completed, a heating process of increasing a temperature of the substrate from the first temperature to the second temperature is started.

4. The substrate processing method of claim 1, wherein a carrier gas for the carboxyl group-containing fluid is supplied in (a), and a supply of the carrier gas is stopped or a supply amount of the carrier gas is reduced in (b).

5. The substrate processing method of claim 1, wherein a temperature of the substrate in (c) is set to be higher than a temperature of the substrate in (a).

6. The substrate processing method of claim 1, wherein the second temperature is set to a temperature at which the crystal grain size becomes a desired value.

7. The substrate processing method of claim 1, wherein an amount of the impurities present in a process chamber in which the substrate is accommodated after (b) is completed is less than an amount of the impurities present in the process chamber after (a) is completed.

8. The substrate processing method of claim 1, wherein the first temperature in (a) is set to a temperature at which the carboxyl group-containing fluid does not liquefy.

9. The substrate processing method of claim 1, wherein (a) and (b) are performed in a same process chamber, and an exhaust flow rate out of the process chamber in (b) is set to be greater than an exhaust flow rate out of the process chamber in (a).

10. The substrate processing method of claim 1, wherein the carboxyl group-containing fluid comprises formic acid or acetic acid.

11. The substrate processing method of claim 1, wherein the metal-containing film comprises at least one among a copper-containing film, a cobalt-containing film and a tungsten-containing film.

12. The substrate processing method of claim 1, wherein (a), (b) and (c) are performed consecutively in a same process chamber.

13. The substrate processing method of claim 1, wherein the substrate is processed such that a temperature elevating rate in (c) is set to be higher than a temperature elevating rate in (a).

14. The substrate processing method of claim 1, wherein, in (c), the substrate is heated to the second temperature such that growth rates of adjacent crystal grains are different from each other.

15. The substrate processing method of claim 1, wherein, (c) is performed after a combination of (a) and (b) is performed one or more times.

16. The substrate processing method of claim 1, wherein, (c) is performed after a combination of (a) and (b) is performed two or more times.

17. The substrate processing method of claim 1, wherein a combination of (a), (b) and (c) is performed two or more times.

18. A method of manufacturing a semiconductor device, comprising the method of claim 1.

19. A substrate processing apparatus comprising:
a supplier configured to be capable of supplying a carboxyl group-containing fluid to a substrate provided with a metal-containing film, wherein the substrate is accommodated in a process chamber;
an exhauster configured to be capable of exhausting an inner atmosphere of the process chamber;
a heater configured to be capable of heating the substrate; and
a controller configured to be capable of controlling the supplier, the exhauster and the heater to perform:
(a) removing impurities from the metal-containing film by supplying the carboxyl group-containing fluid to the substrate at a first temperature while maintaining an inner pressure of the process chamber at a first pressure;
(b) setting the inner pressure of the process chamber to a second pressure lower than the first pressure by exhausting the inner atmosphere of the process chamber while stopping a supply of the carboxyl group-containing fluid; and
(c) increasing a crystal grain size of a metal component in the metal-containing film by heating the substrate to a second temperature higher than the first temperature while maintaining the inner pressure of the process chamber at the second pressure and while exposing the metal-containing film from which the impurities are removed.

20. A non-transitory computer-readable recording medium storing a program that causes a substrate processing apparatus, by a computer, to perform:
(a) removing impurities from a metal-containing film by supplying a carboxyl group-containing fluid to a substrate at a first temperature while maintaining an inner pressure of a process chamber accommodating the substrate provided with the metal-containing film at a first pressure;
(b) setting the inner pressure of the process chamber to a second pressure lower than the first pressure by exhausting an inner atmosphere of the process chamber while stopping a supply of the carboxyl group-containing fluid; and
(c) increasing a crystal grain size of a metal component in the metal-containing film by heating the substrate to a second temperature higher than the first temperature while maintaining the inner pressure of the process chamber at the second pressure and while exposing the metal-containing film from which the impurities are removed.
